(19) United States
(12) Patent Application Publication
(10) Pub. No.: US 2026/0152688 A1
(43) Pub. Date: Jun. 4, 2026

(54) SELECTIVE ETCHANT COMPOSITIONS FOR REDUCING FOAMING

(71) Applicant: ENTEGRIS, INC., Billerica, MA (US)

(72) Inventors: Ju Hee Yeo, Suwon (KR); SeongJin Hong, Cheongju-si (KR); WonLae Kim, Gunpo-si (KR); Yeonhui Kang, Seoul (KR); YoungHun Park, Seoul (KR); Jinwook Jeong, Suwon-si (KR)

(21) Appl. No.: 19/177,329

(22) Filed: Apr. 11, 2025

Related U.S. Application Data
(60) Provisional application No. 63/636,696, filed on Apr. 19, 2024.

(51) Int. Cl. C09K 13/06; C09K 13/04; H10P 50/68

(52) U.S. Cl. CPC C09K 13/06; C09K 13/04; H10P 50/683

(57) ABSTRACT

Selective etchant compositions for reducing foam and related methods are provided herein. The composition may comprise a phosphoric acid; an inhibitor; and 0.01% to 5% by weight of a defoaming agent based on a total weight of the composition. The defoaming agent may comprise at least one of an alkyl carbamate compound, a bicarbonate compound, a sulfuric acid compound, or any combination thereof.

### CROSS-REFERENCE TO RELATED APPLICATIONS

This application claims the benefit under 35 USC 119 of U.S. Provisional Patent Application No. 63/636,696, filed Apr. 19, 2024, the disclosure of which is hereby incorporated herein by reference in its entirety.

### FIELD

The present disclosure relates to selective etchant compositions for reducing foam and related methods.

### BACKGROUND

Selective nitride etching can result in the undesirable creation of foam and silicon oxide regrowth.

### SUMMARY

Some embodiments relate to a composition. In some embodiments, the composition comprises a phosphoric acid. In some embodiments, the composition comprises an inhibitor. In some embodiments, the composition comprises 0.01% to 5% by weight of a defoaming agent based on a total weight of the composition. In some embodiments, the defoaming agent comprises at least one of an alkyl carbamate compound, a bicarbonate compound, a sulfuric acid compound, or any combination thereof.

Some embodiments relate to a method for etching. In some embodiments, the method comprises one or more of the following steps: obtaining a structure comprising a silicon nitride and a silicon oxide; and contacting the structure with a composition to remove at least a portion of the silicon nitride. The composition may comprise a phosphoric acid, an inhibitor, and 0.01% to 5% by weight of a defoaming agent based on a total weight of the composition. In some embodiments, the defoaming agent comprises at least one of an alkyl carbamate compound, a bicarbonate compound, a sulfuric acid compound, or any combination thereof.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method 100 for removing at least a portion of the silicon nitride, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “silicon nitride” refers to a substance comprising silicon and nitrogen. In some embodiments, for example, a silicon nitride comprises at least one of reaction bonded silicon nitride (RBSN), hot pressed silicon nitride (HPSN), sintered silicon nitrides (SSN), or any combination thereof.

As used herein, the term “silicon oxide” silicon oxide (SiOₓ), e.g., SiO₂, “thermal oxide” (ThOx), and the like. In some embodiments, for example, a silicon oxide comprises at least one of crystalline silica, amorphous silica, or any combination thereof.

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, alkynyls, and/or cycloalkyls.

Manufacture of microelectronic devices and fabrication of semiconductors materials can involve selective etching of materials. Conventional selective nitride etchants can foam when nitrogen is added during the etching process and can also suppress silicon oxide (SiOₓ) regrowth. Additionally, the amount of foam present increased as the amount of SiOₓ inhibitor increased with current selective nitride etchants. The suppression of SiOₓ regrowth and increased foam, if any at all, is undesirable.

Some embodiments relate to selective etchant compositions for reducing foam and related methods. The reduced foaming selective nitride etchant compositions maintains the suppression of SiOₓ regrowth and reduces the amount of foam generated during the etching process without deteriorating etching performance. In some embodiments, the composition comprises at least one of a phosphoric acid (H₃PO₄), an inhibitor, a defoaming agent, or any combination thereof. The composition comprises 0.01% to 5% by weight of a defoaming agent based on a total weight of the composition. In some embodiments, the defoaming agent includes at least one of an alkyl carbamate compound, a bicarbonate compound, a sulfuric acid compound, or any combination thereof.

The composition may comprise a phosphoric acid. In some embodiments, the composition comprises 75% to 90% by weight of the phosphoric acid based on a total weight of the composition or any range or subrange between 75% to 90%. In some embodiments, the composition comprises 75% to 89%, 75% to 88%, 75% to 87%, 75% to 86%, 75% to 85%, 75% to 84%, 75% to 83%, 75% to 82%, 75% to 81%, 75% to 80%, 75% to 79%, 75% to 78%, 75% to 77%, 75% to 76%, 76% to 90%, 77% to 90%, 78% to 90%, 79% to 90%, 80% to 90%, 81% to 90%, 82% to 90%, 83% to 90%, 84% to 90%, 85% to 90%, 86% to 90%, 87% to 90%, 88% to 90%, or 89% to 90% by weight of the phosphoric acid based on the total weight of the composition.

The one or more components of the composition may comprise an inhibitor. The inhibitor may increase the selective etching of silicon nitride (Si₃N₄) and Si₃N₄-to- SiO₂ layers when the inhibitor is added in phosphoric acid (H₃PO₄). A SiOₓ inhibitor, for example and without limitation, may be added in H₃PO₄ to increase the etching rate of silicon nitride with an increase to Si₃N₄-to- SiO₂ etch selectivity. With an increase in etching rate for silicon nitride, the silicon nitride may be removed faster thereby decreasing or suppressing the etching rate of silicon oxide. The inhibitor may suppress SiOₓ regrowth. The addition of the inhibitor to H₃PO₄, may suppress etching of SiOₓ more than that of silicon nitride. SiOₓ regrowth is thereby limited or suppressed. Non-limiting examples of the inhibitor include, for example and without limitation, at least one of a polyethylenimine (PEI), a polyethylene, a polyvinylpyrrolidone, a silicic acid, a polyethylene glycol, or any combination thereof. In some embodiments, the inhibitor comprises a polyethylenimine. In some embodiments, the inhibitor comprises a polyethylene. In some embodiments, the inhibitor comprises a polyvinylpyrrolidone. In some embodiments, the inhibitor comprises a silicic acid. In some embodiments, the inhibitor comprises a polyethylene glycol.

In some embodiments, the inhibitor comprises a regrowth inhibitor. Non-limiting examples of regrowth inhibitor include, for example and without limitation, at least one of 1-[3-(trimethoxysilyl)propyl]urea, 3-aminopropylsilantriol, alkylamino, alkoxysilane, alkylamino silane compounds, hydroxyl silane compounds, or any combination thereof. In some embodiments, the inhibitor is 1-[3-(trimethoxysilyl)propyl]urea. In some embodiments, the regrowth inhibitor is 3-aminopropylsilantriol. In some embodiments, the regrowth inhibitor comprises alkylamino alkoxysilane. In some embodiments, the regrowth inhibitor comprises alkylamino hydroxyl silane compounds.

The composition may comprise 0.01% to 10% by weight of a regrowth inhibitor based on the total weight of the composition, or any range or subrange between 0.01% and 10%. In some embodiments, the composition comprises 0.01% to 9.5%, 0.01% to 9%, 0.01% to 8.5%, 0.01% to 8%, 0.01% to 7.5%, 0.01% to 7%, 0.01% to 6.5%, 0.01% to 6%, 0.01% to 5.5%, 0.01% to 5%, 0.01% to 4.5%, 0.01% to 4%, 0.01% to 3.5%, 0.01% to 3%, 0.01% to 2.5%, 0.01% to 2%, 0.01% to 1.5%, 0.01% to 1%, 0.01% to 0.8%, 0.01% to 0.6%, 0.01% to 0.5%, 0.01% to 0.4%, 0.01% to 0.2%, 0.01% to 0.1%, 0.01% to 0.08%, 0.01% to 0.06%, 0.01% to 0.05%, 0.01% to 0.04%, or 0.01% to 0.02% by weight of a regrowth inhibitor based on the total weight of the composition. In some embodiments, the composition comprises 0.1% to 10%, 1% to 10%, 1.5% to 10%, 2% to 10%, 2.5% to 10%, 3% to 10%, 3.5% to 10%, 4% to 10%, 4.5% to 10%, 5% to 10%, 5.5% to 10%, 6% to 10%, 6.5% to 10%, 7% to 10%, 7.5% to 10%, 8% to 10%, 8.5% to 10%, 9% to 10%, or 9.5% to 10% by weight of a regrowth inhibitor based on the total weight of the composition.

In some embodiments, the inhibitor is an oxidation inhibitor. Non-limiting examples of oxidation inhibitor include, for example and without limitation, comprise tetramethylammonium silicate.

The composition may comprise 0.01% to 10% by weight of an oxidation inhibitor based on the total weight of the composition, or any range or subrange between 0.01% and 10%. In some embodiments, the composition comprises 0.01% to 9.5%, 0.01% to 9%, 0.01% to 8.5%, 0.01% to 8%, 0.01% to 7.5%, 0.01% to 7%, 0.01% to 6.5%, 0.01% to 6%, 0.01% to 5.5%, 0.01% to 5%, 0.01% to 4.5%, 0.01% to 4%, 0.01% to 3.5%, 0.01% to 3%, 0.01% to 2.5%, 0.01% to 2%, 0.01% to 1.5%, 0.01% to 1%, 0.01% to 0.8%, 0.01% to 0.6%, 0.01% to 0.5%, 0.01% to 0.4%, 0.01% to 0.2%, 0.01% to 0.1%, 0.01% to 0.08%, 0.01% to 0.06%, 0.01% to 0.05%, 0.01% to 0.04%, or 0.01% to 0.02% by weight of an oxidation inhibitor based on the total weight of the composition. In some embodiments, the composition comprises 0.1% to 10%, 1% to 10%, 1.5% to 10%, 2% to 10%, 2.5% to 10%, 3% to 10%, 3.5% to 10%, 4% to 10%, 4.5% to 10%, 5% to 10%, 5.5% to 10%, 6% to 10%, 6.5% to 10%, 7% to 10%, 7.5% to 10%, 8% to 10%, 8.5% to 10%, 9% to 10%, or 9.5% to 10% by weight of an oxidation inhibitor based on the total weight of the composition.

The one or more components of the composition may comprise 0.01% to 5% by weight of a defoaming agent based on a total weight of the composition. The defoaming agent may reduce foam during the etching process. The inhibitor in the composition may create the foam. Additionally, the defoaming agent may suppress bubbles generated from the introduction of nitrogen (N₂) gas during the etching process. Non-limiting examples of the defoaming agent include, for example and without limitation, at least one of an alkyl carbamate compound, a bicarbonate compound, a sulfuric acid compound, or any combination thereof. In some embodiments, the defoaming agent comprises an alkyl carbamate. In some embodiments, the defoaming agent comprises a bicarbonate compound. In some embodiments, the defoaming agent comprises a sulfuric acid compound.

The composition may comprise 0.01% to 5% by weight of a defoaming agent based on a total weight of the composition, or any range or subrange between 0.01% and 5%. In some embodiments, the composition comprises 0.01% to 4.5%, 0.01% to 4%, 0.01% to 3.5%, 0.01% to 3%, 0.01% to 2.5%, 0.01% to 2%, 0.01% to 1.5%, 0.01% to 1%, 0.01% to 0.8%, 0.01% to 0.6%, 0.01% to 0.5%, 0.01% to 0.4%, 0.01% to 0.2%, 0.01% to 0.1%, 0.01% to 0.08%, 0.01% to 0.06%, 0.01% to 0.05%, 0.01% to 0.04%, or 0.01% to 0.02% by weight of defoaming agent based on the total weight of the composition. In some embodiments, the composition comprises 0.1% to 5%, 1% to 5%, 1.5% to 5%, 2% to 5%, 2.5% to 5%, 3% to 5%, 3.5% to 5%, 4% to 5%, 4.5% to 5%, 4.6% to 5%, 4.7% to 5%, 4.8% to 5%, or 4.9% to 5% by weight of defoaming agent based on the total weight of the composition.

The defoaming agent may comprise an alkyl carbamate compound. Non-limiting examples of the alkyl carbamate compound include, for example and without limitation, at least one of a methyl carbamate, an ethyl carbamate, a propyl carbamate, a butyl carbamate, or any combination thereof. In some embodiments, the alkyl carbamate compound comprises a methyl carbamate. In some embodiments, the alkyl carbamate compound comprises an ethyl carbamate. In some embodiments, the alkyl carbamate compound comprises a propyl carbamate. In some embodiments, the alkyl carbamate compound comprises a butyl carbamate.

The alkyl carbamate compound may comprise a compound of the formula:

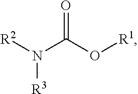

where R¹ is a hydrogen or an alkyl, R² is a hydrogen or an alkyl, and R³ is a hydrogen or an alkyl, as defined herein.

The alkyl carbamate compound may comprise a compound of the formula:

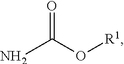

where R¹ is a hydrogen or an alkyl, as defined herein.

The defoaming agent may comprise a bicarbonate compound. In some embodiments, the bicarbonate compound comprises a bicarbonate salt. The bicarbonate salt may comprise a carbonate anion and a nitrogen-containing cation. In some embodiments, the nitrogen-containing cation comprises an alkyl ammonium cation. The alkyl ammonium cation may comprise a C₁-C₈ alkyl. Non-limiting examples of the bicarbonate compound include, for example and without limitation, at least one of a sodium bicarbonate, a potassium bicarbonate, a lithium bicarbonate, a cesium bicarbonate, a calcium bicarbonate, a magnesium bicarbonate, an ammonium bicarbonate, a choline bicarbonate, a triethylammonium bicarbonate, a tetraethylammonium bicarbonate, or any combination thereof. In some embodiments, the bicarbonate compound comprises a sodium bicarbonate. In some embodiments, the bicarbonate compound comprises a potassium bicarbonate. In some embodiments, the bicarbonate compound comprises a lithium bicarbonate. In some embodiments, the bicarbonate compound comprises a cesium bicarbonate. In some embodiments, the bicarbonate compound comprises a calcium bicarbonate. In some embodiments, the bicarbonate compound comprises a magnesium bicarbonate. In some embodiments, the bicarbonate compound comprises an ammonium bicarbonate. In some embodiments, the bicarbonate compound comprises a choline bicarbonate. In some embodiments, the bicarbonate compound comprises a triethylammonium bicarbonate. In some embodiments, the bicarbonate compound comprises a tetraethylammonium bicarbonate.

The defoaming agent may comprise a sulfuric acid compound. In some embodiments, the sulfuric acid compound comprises sulfuric acid. In some embodiments, the sulfuric acid comprises an acid of the formula: H₂SO₄.

The composition may comprise 75% to 90% by weight of the phosphoric acid based on the total weight of the composition, or any range or subrange between 75% and 90%. In some embodiments, the composition comprises 76% and 90%, 77% and 90%, 78% and 90%, 79% and 90%, 80% and 90%, 81% and 90%, 82% and 90%, 83% and 90%, 84% and 90%, 85% and 90%, 86% and 90%, 87% and 90%, 88% and 90%, 89% and 90% % by weight of the phosphoric acid based on the total weight of the composition. In some embodiments, the composition comprises 75% and 89%, 75% and 88%, 75% and 87%, 75% and 86%, 75% and 85%, 75% and 84%, 75% and 83%, 75% and 82%, 75% and 81%, 75% and 80%, 75% and 79%, 75% and 78%, 75% and 77%, 75% and 76% by weight of the phosphoric acid based on the total weight of the composition.

In some embodiments, the composition may comprise 0.01% to 10% by weight of a regrowth inhibitor based on the total weight of the composition, or any range or subrange between 0.01% and 10%. In some embodiments, the composition comprises 0.01% to 9.5%, 0.01% to 9%, 0.01% to 8.5%, 0.01% to 8%, 0.01% to 7.5%, 0.01% to 7%, 0.01% to 6.5%, 0.01% to 6%, 0.01% to 5.5%, 0.01% to 5%, 0.01% to 4.5%, 0.01% to 4%, 0.01% to 3.5%, 0.01% to 3%, 0.01% to 2.5%, 0.01% to 2%, 0.01% to 1.5%, 0.01% to 1%, 0.01% to 0.8%, 0.01% to 0.6%, 0.01% to 0.5%, 0.01% to 0.4%, 0.01% to 0.2%, 0.01% to 0.1%, 0.01% to 0.08%, 0.01% to 0.06%, 0.01% to 0.05%, 0.01% to 0.04%, or 0.01% to 0.02% by weight of a regrowth inhibitor based on the total weight of the composition. In some embodiments, the composition comprises 0.1% to 10%, 1% to 10%, 1.5% to 10%, 2% to 10%, 2.5% to 10%, 3% to 10%, 3.5% to 10%, 4% to 10%, 4.5% to 10%, 5% to 10%, 5.5% to 10%, 6% to 10%, 6.5% to 10%, 7% to 10%, 7.5% to 10%, 8% to 10%, 8.5% to 10%, 9% to 10%, or 9.5% to 10% by weight of a regrowth inhibitor based on the total weight of the composition.

In some embodiments, the composition may comprise 0.01% to 10% by weight of an oxidation inhibitor based on the total weight of the composition, or any range or subrange between 0.01% and 10%. In some embodiments, the composition comprises 0.01% to 9.5%, 0.01% to 9%, 0.01% to 8.5%, 0.01% to 8%, 0.01% to 7.5%, 0.01% to 7%, 0.01% to 6.5%, 0.01% to 6%, 0.01% to 5.5%, 0.01% to 5%, 0.01% to 4.5%, 0.01% to 4%, 0.01% to 3.5%, 0.01% to 3%, 0.01% to 2.5%, 0.01% to 2%, 0.01% to 1.5%, 0.01% to 1%, 0.01% to 0.8%, 0.01% to 0.6%, 0.01% to 0.5%, 0.01% to 0.4%, 0.01% to 0.2%, 0.01% to 0.1%, 0.01% to 0.08%, 0.01% to 0.06%, 0.01% to 0.05%, 0.01% to 0.04%, or 0.01% to 0.02% by weight of a oxidation inhibitor based on the total weight of the composition. In some embodiments, the composition comprises 0.1% to 10%, 1% to 10%, 1.5% to 10%, 2% to 10%, 2.5% to 10%, 3% to 10%, 3.5% to 10%, 4% to 10%, 4.5% to 10%, 5% to 10%, 5.5% to 10%, 6% to 10%, 6.5% to 10%, 7% to 10%, 7.5% to 10%, 8% to 10%, 8.5% to 10%, 9% to 10%, or 9.5% to 10% by weight of a oxidation inhibitor based on the total weight of the composition.

In some embodiments, the composition, when mixed at 200 revolutions per minute (RPM) and at 25° C. to 160° C., produces less foam than a composition which does not comprise the defoaming agent. In some embodiments, the composition when mixed at 200 RPM and at a temperature from 25° C. to 160° C., or any range or subrange therebetween. In some embodiments, the temperature ranges from 30° C. and 160° C., 40° C. and 160° C., 40° C. and 160° C., 50° C. and 160° C., 60° C. and 160° C., 70° C. and 160° C., 80° C. and 160° C., 90° C. and 160° C., 100° C. and 160° C., 110° C. and 160° C., 120° C. and 160° C., 130° C. and 160° C., 140° C. and 160° C., 150° C. and 160° C. at 200 RPM.

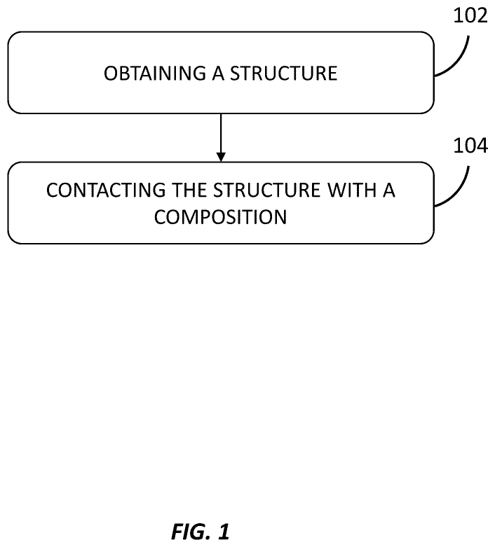

FIG. 1 is a flowchart of a method 100 for removing at least a portion of the silicon nitride, according to some embodiments. As shown in FIG. 1, in some embodiments, the method 100 may comprise one or more of the following steps: a step 102 of obtaining a structure; a step 104 of contacting the structure with a composition. In some embodiments, the contacting comprising mixing, combining, adding, or otherwise bringing into close or immediate proximity so as to remove at least a portion of the silicon nitride.

The conditions of the contacting may comprise at least one of a duration, a temperature, or any combination thereof. The duration should be sufficient to least a portion of the silicon nitride. The duration of exposure to the composition and the temperature of the composition may be selected based on a desired amount of removal of the silicon nitride from a structure. The duration of the contacting should balance process control and quality with process efficiency and throughput of the etching process and the semiconductor fabrication line. Examples of a suitable duration may be in a range of 5 minutes to 300 minutes, or any range or subrange therebetween, such as, 10 minutes to 60 minutes. Examples of a suitable temperature is a temperature in a range of 100° C. to 250° C. (e.g., 100° C. to 180° C., 150° C. to 180° C.), or any range or subrange therebetween. Such contacting times and temperatures are illustrative, and other suitable contacting times and temperature conditions may be used herein without departing from this disclosure.

At step 102, in some embodiments, a structure is obtained. The structure may comprise a silicon nitride and a silicon oxide. At step 104, the structure may be contacted with a composition to remove at least a portion of the silicon nitride.

The composition may comprise a phosphoric acid. The composition may comprise an inhibitor. The composition may comprise 0.01% to 5% by weight of a defoaming agent based on a total weight of the composition, or any combination thereof. The defoaming agent may comprise at least one of an alkyl carbamate compound, a bicarbonate compound, a sulfuric acid compound, or any combination thereof. In some embodiments, the defoaming agent is selected from the group consisting of an alkyl carbamate compound, a bicarbonate compound, a sulfuric acid compound, and any combination thereof. It will be appreciated that other compositions disclosed herein may be used without departing from this disclosure. In some embodiments, the composition removes a greater proportion of the silicon nitride than the silicon oxide.

The alkyl carbamate compound may comprise a compound of the formula:

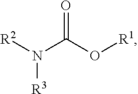

where R¹ is a hydrogen or an alkyl, R² is a hydrogen or an alkyl, and R³ is a hydrogen or an alkyl, as defined herein.

In some embodiments, the bicarbonate compound comprises a bicarbonate salt. The bicarbonate salt may comprise a carbonate anion. The bicarbonate salt may comprise a nitrogen-containing cation.

The sulfuric acid compound may comprise sulfuric acid.

As used herein, the term “contacting” refers to bringing two or more components into immediate or close proximity, or into direct contact.

Any one or more of the embodiments disclosed herein shall be understood to be combinable without departing from the scope or spirit of the disclosure.

### Aspects

Various Aspects are described below. It is to be understood that any one or more of the features recited in the following Aspect(s) can be combined with any one or more other Aspect(s).
Aspect 1. A composition comprising:
   a phosphoric acid;
   an inhibitor; and
   0.01% to 5% by weight of a defoaming agent based on a total weight of the composition,
   wherein the defoaming agent comprises at least one of an alkyl carbamate compound, a bicarbonate compound, a sulfuric acid compound, or any combination thereof.
Aspect 2. The composition according to Aspect 1, wherein the defoaming agent is selected from the group consisting of an alkyl carbamate compound, a bicarbonate compound, a sulfuric acid compound, and any combination thereof.
Aspect 3. The composition according to Aspect 1, wherein the alkyl carbamate compound comprises a compound of the formula:

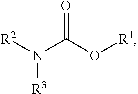

where:
R¹ is a hydrogen or an alkyl;
R² is a hydrogen or an alkyl; and
R³ is a hydrogen or an alkyl.
Aspect 4. The composition according to any of Aspects 1-3, wherein R¹ is a C₁-C₈ alkyl.
Aspect 5. The composition according to Aspect 1, wherein the alkyl carbamate compound comprises a compound of the formula:

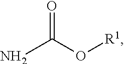

where:
R¹ is a hydrogen or an alkyl.
Aspect 6. The composition according to any one of Aspects 1-5, wherein R¹ is a C₁-C₈ alkyl.
Aspect 7. The composition according to Aspect 1, wherein the alkyl carbamate compound comprises at least one of a methyl carbamate, an ethyl carbamate, a propyl carbamate, a butyl carbamate, or any combination thereof.
Aspect 8. The composition according to Aspect 1, wherein the bicarbonate compound comprises:
   a bicarbonate salt,
   wherein the bicarbonate salt comprises:
   a carbonate anion; and
   a nitrogen-containing cation.
Aspect 9. The composition according to any one of Aspects 1-8, wherein the nitrogen-containing cation comprises an alkyl ammonium cation.
Aspect 10. The composition according to any one of Aspects 9, wherein the alkyl ammonium cation comprises a C₁-C₈ alkyl.
Aspect 11. The composition according to Aspect 1, wherein the bicarbonate compound comprises at least one of a sodium bicarbonate, a potassium bicarbonate, a lithium bicarbonate, a cesium bicarbonate, a calcium bicarbonate, a magnesium bicarbonate, an ammonium bicarbonate, a choline bicarbonate, a triethylammonium bicarbonate, a tetraethylammonium bicarbonate, or any combination thereof.
Aspect 12. The composition according to Aspect 1, wherein the sulfuric acid compound comprises sulfuric acid.
Aspect 13. The composition according to Aspect 1, wherein the composition, when mixed at 200 RPM and at 25° C. to 160° C., produces less foam than a composition which does not comprise the defoaming agent.
Aspect 14. The composition according to Aspect 1, wherein the composition comprises: 75% to 90% by weight of the phosphoric acid based on the total weight of the composition; 0.01% to 10% by weight of a regrowth inhibitor based on the total weight of the composition; and 0.01% to 10% by weight of an oxidation inhibitor based on the total weight of the composition.
Aspect 15. A method comprising:
obtaining a structure comprising a silicon nitride and a silicon oxide; and
contacting the structure with a composition to remove at least a portion of the silicon nitride,
wherein the composition comprises:
   a phosphoric acid;
   an inhibitor; and 0.01% to 5% by weight of a defoaming agent based on a total weight of the composition,
      wherein the defoaming agent comprises at least one of an alkyl carbamate compound, a bicarbonate compound, a sulfuric acid compound, or any combination thereof.
Aspect 16. The method according to Aspect 15, wherein the composition removes a greater proportion of the silicon nitride than the silicon oxide.
Aspect 17. The method according to Aspect 15, wherein the defoaming agent is selected from the group consisting of an alkyl carbamate compound, a bicarbonate compound, a sulfuric acid compound, and any combination thereof.
Aspect 18. The method according to Aspect 15, wherein the alkyl carbamate compound comprises a compound of the formula:

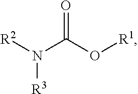

where:
R¹ is a hydrogen or an alkyl;
R² is a hydrogen or an alkyl; and
R³ is a hydrogen or an alkyl.
Aspect 19. The method according to Aspect 15, wherein the bicarbonate compound comprises:
a bicarbonate salt,
   wherein the bicarbonate salt comprises:
a carbonate anion; and
a nitrogen-containing cation.
Aspect 20. The method according to Aspect 15, wherein the sulfuric acid compound comprises sulfuric acid.

### Example

Various compositions were prepared and compared to a control composition. The compositions, as well as the control composition are summarized in Table 1 below. The control composition was prepared from a base composition comprising H₂SO₄, regrowth inhibitor (Re Inh.), and oxidation inhibitor (Ox Inh.).

TABLE 1

| | | | | | | Foam | |
|---|---|---|---|---|---|---|---|
| | | | | | | Room | |
| | | Composition | | | | Temp | |
| | Defoamer | | | | Add | (Foam | High |
| Example | Agent | H₂SO₄ | Re Inh. | Ox Inh. | Defoamer | Height) | Temp |
| Control | N/A | X | X | X | N/A | 44-50 | Foam |
| | | | | | | mm | |
| Composition | Methyl | X | X | X | X | 20-22 | Less |
| 1 | carbamate | | | | | mm | Foam |
| Composition | Ammonium | X | X | X | X | 40 mm | Foam |
| 2 | dihydrogen | | | | | | |
| | phosphate | | | | | | |
| Composition | Diammonium | X | X | X | X | 40 mm | Foam |
| 3 | phosphate | | | | | | |
| Composition | Sulfuric acid | X | X | X | X | 20 mm | Less |
| 4 | | | | | | | Foam |
| Composition | Nitric acid | X | X | X | X | 48-50 | Foam |
| 5 | | | | | | mm | |
| Composition | Ammonium | X | X | X | X | No | Foam |
| 6 | bicarbonate | | | | | Foam | |
| Composition | Ammonium | X | X | X | X | 50-55 | Foam |
| 7 | sulfate | | | | | mm | |
| Composition | Tetraethyl | X | X | X | X | 6-8 | Less |
| 8 | bicarbonate | | | | | mm | Foam |

Each of the compositions foam height and appearance was evaluated. Preparation of the control and compositions included adding 0.02 mole percent (mol. %) of the respective defoaming agent to a solution of H₂SO₄, regrowth inhibitor, and oxidation inhibitor. After adding the defoaming agent, the solution and defoaming agent was mixed. Next, 100 ml of the mixture was poured into a 250 milliliter (ml) mass cylinder. Nitrogen (N₂) gas was added to the mass cylinder for 1 minute at room temperature to create bubbling. The foam height and appearance of foam was then measured.

A silicon nitride wafer was contacted with a 100:1 hydrofluoric (HF) acid solution for 60 seconds to remove the surface oxide. The silicon nitride wafer was then contacted with each of the compositions and the control at 160 degrees Celsius (° C.) for 30 minutes. Next, the silicon nitride wafer was rinsed in hot deionized water. An oxide wafer was then contacted with the composition at 160° C. for 30 minutes. Next, the oxide wafer was rinsed in hot deionized water. The silicon nitride wafer and the oxide wafer were measured before and after testing using ellipsometry.

As shown above in Table 1, the compositions with the defoaming agent comprising methyl carbamate, ammonium dihydrogen phosphate, diammonium, sulfuric acid, ammonium bicarbonate, and tetraethyl bicarbonate measured less foam or no foam at room temperature. The inventive formulations also provided foam reduction at 150° C. to 180° C. The methyl carbamate, tetraethyl bicarbonate, and sulfuric acid showed a reduction in foam height at high temperatures.

Silicon oxide regrowth and etch rate was measured. Table 2 below, show a reduction in foam height at room temperature (RT) and a reduction in etch rate for silicon nitride and silicon oxide using Composition 1 when compared to the control. Additionally, the selectivity of nitride increased using Composition 1. Silicon regrowth did not change when compared to the control.

TABLE 2

| | | | | | | Etch Rate | | | Si |
|---|---|---|---|---|---|---|---|---|---|
| | | | Re | Add | Foam | (A/min) | | | regrowth |
| Composition | Defoamer | H₂SO₄ | Inh. | Defoamer | RT | SiNₓ | SiOₓ | Selectivity | [Si ppm] |
| Control | N//A | X | X | N/A | 44-50 | 39.5 | 0.9 | 42 | 700 |
| | | | | | mm | | | | |
| Composition | Methyl | X | X | X | 20-22 | | | 47 | 700 |
| 1 | carbamate | | | | mm | | | | |

A preferred range for SiNx etch is between 30 and 120 Angstroms per min. A preferred range for SiOₓ etch is between 0.01 and 3.0 Angstroms per min. Selectivity may range from 0 to about 1000. Si regrowth may range from 0 to 1000 ppm.

What is claimed is:

1. A composition comprising:
a phosphoric acid;
an inhibitor; and
0.01% to 5% by weight of a defoaming agent based on a total weight of the composition,
wherein the defoaming agent comprises at least one of an alkyl carbamate compound, a bicarbonate compound, a sulfuric acid compound, or any combination thereof.

2. The composition of claim 1, wherein the defoaming agent is selected from the group consisting of an alkyl carbamate compound, a bicarbonate compound, a sulfuric acid compound, and any combination thereof.

3. The composition of claim 1, wherein the defoaming agent comprises an alkyl carbamate compound of the formula: 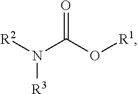
where:
R¹ is a hydrogen or an alkyl;
R² is a hydrogen or an alkyl; and
R³ is a hydrogen or an alkyl.

4. The composition of claim 3, wherein R¹ is a C₁-C₈ alkyl.

5. The composition of claim 1, wherein the defoaming agent comprises an alkyl carbamate compound of the formula: 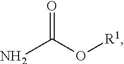
where:
R¹ is a hydrogen or an alkyl.

6. The composition of claim 5, wherein R¹ is a C₁-C₈ alkyl.

7. The composition of claim 1, wherein the defoaming agent comprises an alkyl carbamate compound selected from the group consisting of a methyl carbamate, an ethyl carbamate, a propyl carbamate, a butyl carbamate, or any combination thereof.

8. The composition of claim 1, wherein the bicarbonate compound comprises:
a bicarbonate salt,
wherein the bicarbonate salt comprises:
a carbonate anion; and
a nitrogen-containing cation.

9. The composition of claim 8, wherein the nitrogen-containing cation comprises an alkyl ammonium cation.

10. The composition of claim 9, wherein the alkyl ammonium cation comprises a C₁-C₈ alkyl.

11. The composition of claim 1, wherein the bicarbonate compound comprises at least one of a sodium bicarbonate, a potassium bicarbonate, a lithium bicarbonate, a caesium bicarbonate, a calcium bicarbonate, a magnesium bicarbonate, an ammonium bicarbonate, a choline bicarbonate, a triethylammonium bicarbonate, a tetraethylammonium bicarbonate, or any combination thereof.

12. The composition of claim 1, wherein the sulfuric acid compound comprises sulfuric acid.

13. The composition of claim 1, wherein the composition, when mixed at 200 RPM and at 25° C. to 160° C., produces less foam than a composition which does not comprise the defoaming agent.

14. The composition of claim 1, wherein the composition comprises:
75% to 90% by weight of the phosphoric acid based on the total weight of the composition;
0.01% to 10% by weight of a regrowth inhibitor based on the total weight of the composition; and
0.01% to 10% by weight of an oxidation inhibitor based on the total weight of the composition.

15. A method comprising:
obtaining a structure comprising a silicon nitride and a silicon oxide; and
contacting the structure with a composition to remove at least a portion of the silicon nitride,
wherein the composition comprises:
a phosphoric acid;
an inhibitor; and
0.01% to 5% by weight of a defoaming agent based on a total weight of the composition,
wherein the defoaming agent comprises at least one of an alkyl carbamate compound, a bicarbonate compound, a sulfuric acid compound, or any combination thereof.

16. The method of claim 15, wherein the composition removes a greater proportion of the silicon nitride than the silicon oxide.

17. The method of claim 15, wherein the defoaming agent is selected from the group consisting of an alkyl carbamate compound, a bicarbonate compound, a sulfuric acid compound, and any combination thereof.

18. The method of claim 15, wherein the defoaming agent comprises an alkyl carbamate compound of the formula: 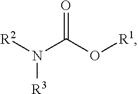
where:
R¹ is a hydrogen or an alkyl;
R² is a hydrogen or an alkyl; and
R³ is a hydrogen or an alkyl.

19. The method of claim 15, wherein defoaming agent comprises a bicarbonate compound, where the bicarbonate compound is a bicarbonate salt comprising a carbonate anion and a nitrogen-containing cation.

20. The method of claim 15, wherein the defoaming agent comprises a sulfuric acid compound, and the sulfuric acid compound comprises sulfuric acid.
